(19) United States
(12) Patent Application Publication
(10) Pub. No.: US 2026/0176746 A1
(43) Pub. Date: Jun. 25, 2026

(54) FLOWABLE FILM DEPOSITION METHOD AND SYSTEM

(71) Applicant: ASM IP Holding B.V., Almere (NL)

(72) Inventors: Ranjit Rohidas Borude, Leuven (BE); Timothee Blanquart, Tama-shi, Tokyo (JP); Makoto Igarashi, Fuchu-shi, Tokyo (JP); René Henricus Jozef Vervuurt, Leuven (BE); Pamarti Viswanath, Tokyo (JP); Jhoelle Roche Guhit, Tokyo (JP)

(21) Appl. No.: 19/422,992

(22) Filed: Dec. 17, 2025

Related U.S. Application Data
(60) Provisional application No. 63/737,531, filed on Dec. 20, 2024.

(51) Int. Cl. C23C 16/04; C23C 16/34; C23C 16/455; C23C 16/52; C23C 16/56; H01J 37/32; H10P 14/694

(52) U.S. Cl. CPC C23C 16/045; C23C 16/345; C23C 16/45536; C23C 16/45544; C23C 16/45553; C23C 16/52; C23C 16/56; H01J 37/32449; H10P 14/69433; H01J 2237/336

(57) ABSTRACT

Methods and systems suitable for gas-phase processes are disclosed. An exemplary method includes treating a top surface of a substrate to form a treated surface by exposing the top surface to a treatment gas and vacuum ultraviolet radiation and depositing flowable material by providing a precursor and a reactant to form a deposited material. The method can further comprise treating a top surface of the deposited material by providing a cure gas and vacuum ultraviolet radiation. Methods and systems can be used to obtain desired profiles of deposited material on a substrate surface comprising high aspect ratio features.

### CROSS-REFERENCE TO RELATED APPLICATIONS

This application claims priority to U.S. Provisional Patent Application Ser. No. 63/737,531 filed Dec. 20, 2024 titled FLOWABLE FILM DEPOSITION METHOD AND SYSTEM, the disclosure of which is hereby incorporated by reference in its entirety.

### FIELD OF INVENTION

The present disclosure generally relates to methods and systems used in the formation of electronic devices. More particularly, the disclosure relates to methods and systems suitable for depositing and forming films during substrate processing.

### BACKGROUND OF THE DISCLOSURE

Gas-phase reactors, such as chemical vapor deposition (CVD) reactors and the like, can be used for a variety of applications, including depositing materials to form films on substrates. For example, gas-phase reactors can be used to deposit layers on a substrate to form devices, such as semiconductor devices, flat panel display devices, photovoltaic devices, microelectromechanical systems (MEMS), and the like.

In some applications, the substrate includes high aspect ratio features. It may be desirable to fill such features. Flowable deposition processes can be used to fill high aspect ratio features with initially flowable material. While typical flowable deposition processes can work for a variety of applications, existing methods can cause underlayer damage and may not work for reactively high aspect ratio features. Accordingly, improved methods and systems for forming films is desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to improved methods and systems suitable for depositing material on a surface of a substrate. While the ways in which various embodiments of the present disclosure address drawbacks of prior systems and methods are discussed in more detail below, in general, various embodiments of the disclosure provide methods and systems that can be used to, for example, deposit material with reduced seam and/or void formation in material deposited in high aspect ratio (e.g., aspect ratio≥5) features.

As described in more detail below, in accordance with examples of the disclosure, flowable material deposition utilizing a reactor system is disclosed. Examples of the disclosure include use of a vacuum ultraviolet treatment of a substrate comprising gaps prior to depositing the flowable material deposition to improve a wettability of the deposited material and to improve gap-fill performance. In some embodiments, a second vacuum ultraviolet treatment (e.g., a vacuum ultraviolet cure) is performed after material deposition to provide significant advantages in reducing seam and void formation in material deposited within gaps.

Examples of the disclosure are conveniently described in connection with formation of films, such as silicon nitride films, or other deposited layers. However, unless noted otherwise, examples of the disclosure are not so limited.

In accordance with additional embodiments of the disclosure, a reactor system is provided. An exemplary reactor system includes a first reaction chamber configured to deposit a flowable material on a substrate, a reactant source comprising a reactant, a precursor source comprising a silicon precursor, a treatment gas source, a vacuum ultraviolet radiation source configured to generate vacuum ultraviolet radiation, and a controller configured to cause the reactor system to perform a method as described herein. In various embodiments, the treatment gas source comprises a treatment gas comprising one or more of O₂, NH₃, Ar, N₂, He, H₂ and N₂H₂. In various embodiments, the substrate comprises a plurality of gaps. In various embodiments, the reaction system further comprises a cure gas source, wherein the cure gas source comprises one or more of O₂, NH₃, Ar, N₂, He, H₂ and N₂H₂. In various embodiments, the reactant source, the precursor source, the treatment gas source, and the cure gas source are in fluid communication with the first reaction chamber.

In accordance with examples of additional embodiments, the reactor system comprises a second reaction chamber and a wafer handling system. In various embodiments, the wafer handling system is configured to move the substrate from the first reaction chamber to the second reaction chamber, and to any other reaction chambers being used in the reactor system.

In accordance with additional embodiments of the disclosure, a method is provided. An exemplary method includes providing a substrate with a plurality of gaps within a reaction chamber of a reactor system. In various embodiments, the method comprises treating a top surface of the substrate to form a treated surface. The treating step can comprise exposing the top surface to a treatment gas and vacuum ultraviolet radiation. In various embodiments, the treatment gas comprises one or more of O₂, NH₃, Ar, N₂, He, H₂ and N₂H₂. Treating the top surface of the substrate modifies a flowability of the flowable material. In various embodiments, the method comprises depositing a flowable material in the plurality of gaps by providing a precursor and a reactant, wherein the flowable material becomes deposited material formed on the substrate. In exemplary embodiments, the deposited material can be a silicon film (e.g., silicon nitride). In various embodiments, the method further comprises treating a top surface of the deposited material to form a treated deposited material. Treating the top surface of the deposited material can be done by, for example, providing a cure gas and vacuum ultraviolet radiation. In various embodiments, the depositing the flowable material step is carried out in the reaction chamber and the treating the top surface of the deposited material is carried out in a second reaction chamber.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with exemplary embodiments of the disclosure.

FIG. 2 illustrates steps of the method of FIG. 1 in accordance with exemplary embodiments of the disclosure.

FIG. 3 illustrates steps of a method in accordance with exemplary embodiments of the disclosure.

FIG. 4 illustrates a top view of a reactor system in accordance with exemplary embodiments of the disclosure.

FIG. 5 illustrates a top view of a reactor system and process in accordance with exemplary embodiments of the disclosure.

FIG. 6 illustrates a cross sectional view of a reactor in accordance with exemplary embodiments of the disclosure.

It will be appreciated that elements in the figures are illustrated for simplicity and clarity and have not necessarily been drawn to scale. For example, the dimensions of some of the elements in the figures can be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods and systems suitable for use in reactor systems. Such methods and systems can be used to deposit flowable material and treat deposited material during, for example, formation of a device or structure. By way of examples, the methods and systems can be used to deposit material in high aspect ratio features. In this context, high aspect ratio can be an aspect ratio≥20, where an aspect ratio is defined as a ratio of a height (H) to a width (W) of a feature, such as a gap.

As used herein, the terms “precursor” and/or “reactant” can refer to one or more gases/vapors that take part in a chemical reaction or from which a gas-phase substance that takes part in a reaction is derived. In some cases, the terms precursor and reactant can be used interchangeably. The chemical reaction can take place in the gas phase and/or between a gas phase and a surface (e.g., of a substrate or reaction chamber) and/or a species on a surface (e.g., of a substrate or a reaction chamber).

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate. A film or layer may comprise material or a layer with pinholes and/or isolated islands. A film or layer may be at least partially continuous.

The term “deposition process” as used herein can refer to the introduction of precursors (and/or reactants) into a reaction chamber to deposit or form a layer over a substrate. This can include plasma enhanced chemical vapor deposition (“PECVD”), plasma enhanced atomic layer deposition (“PEALD”) and PECVD/PEALD hybrid deposition.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by,” “having,” and their equivalents can refer independently to “typically or broadly comprising,” “comprising,” “consisting essentially of,” or “consisting of” in some embodiments. In this disclosure, any defined meanings do not necessarily exclude ordinary and customary meanings in some embodiments. Further, the term “about” can refer to +/−20, 10, 5, 2, 1 or 0.5 percent of a value, and any value noted herein can be +/−20, 10, 5, 2, 1 or 0.5 percent of the value.

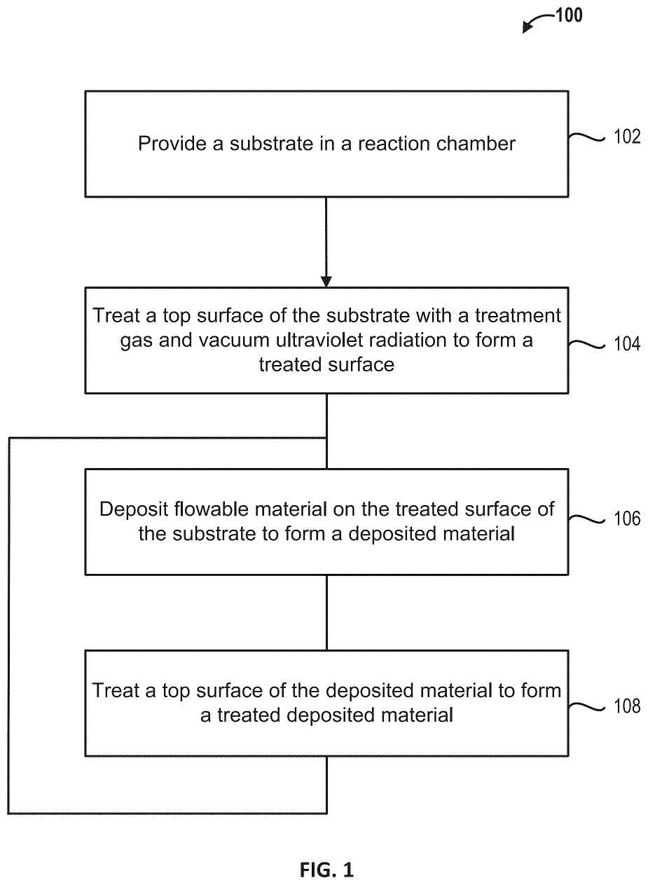

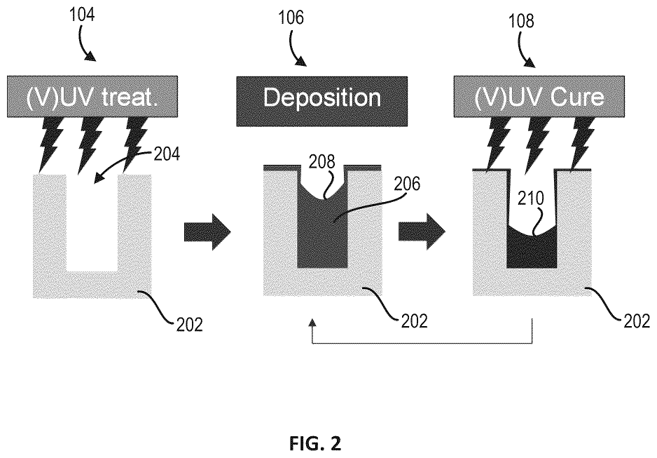

Turning now to the figures, FIG. 1 illustrates a block diagram of an exemplary method 100 according to embodiments of the present disclosure. Additionally, FIG. 2 illustrates steps of method 100 to form a deposited and treated material on a substrate. Method 100 includes providing, a substrate (e.g., a substrate 202), in a reaction chamber (step 102). In various embodiments, the substrate comprises a plurality of gaps (e.g., a gap 204).

In various embodiments, the method 100 comprises treating a top surface of the substrate to form a treated surface (e.g., a treated surface 205) (step 104). In various embodiments, treating the top surface of the substrate can be done by exposing the top surface to a treatment gas and vacuum ultraviolet radiation. During step 104, the substrate is heated to a temperature of between 50° C. and 550° C. or between 65° C. and 110° C. In various embodiments, the treatment gas used during step 104 can comprise one or more of O₂, NH₃, Ar, N₂, He, H₂ and N₂H₂, in any combination. In various embodiments, a pressure in the reaction chamber during the treatment step 104 can be controlled to a pressure of, for example, to between about 7 Torr and about 12 Torr or between about 9 Torr and about 11 Torr. The treatment gas and the vacuum ultraviolet radiation can be introduced at about the same time to the reaction chamber to treat the top surface of the substrate. The vacuum ultraviolet radiation may comprise electromagnetic radiation with a wavelength of about 200 nm to about 500 nm, or at least 150 nm to 200 nm. In various embodiments, the vacuum ultraviolet radiation can be replaced with a wide range ultraviolet radiation. In various embodiments, a power to form the vacuum ultraviolet radiation is between 100 mW/cm² and 200 mW/cm² or between 125 mW/cm² and about 150 mW/cm².

In accordance with embodiments of the disclosed, void free gap-fill can be achieved by flowable deposition in high aspect ratio gaps, in which plasma enhanced polymerization reaction takes place in vapor phase to form or deposit flowable material, which flows inside the gaps. Flowability can depend on substrate surface conditions, e.g., surface energy, wettability, temperature or the like. Tuning these parameters can be used to obtain void free material within the gaps. The step 104 of treating the top surface of the substrate can be used to modify the flowability of any flowable material deposited on the substrate and in the plurality of gaps. Step 104 can improve the wettability of the flowable material and gap fill performance.

Method 100 includes depositing flowable material in the plurality of gaps by providing a precursor and a reactant (step 106). In various embodiments, the flowable material forms deposited material (e.g., deposited material 206). The deposited material has a top surface of the deposited material (e.g., a top surface of the deposited material 208).

In various embodiments, the precursor comprises one or more of silicon, nitrogen, carbon, oxygen and hydrogen. For example, the precursor can be represented by the formula Si_{X}N_{Y}C_{Z}O_{A}H_{N}, where X ranges from 1 to 6 Y ranges from 0 to 6, Z ranges from 0 to 20, A ranges from 0 to 10, and N ranges from 0 to 10. By way of examples, the precursor can be or include methyltrimethoxysilane (MTMS), hexamethyldisiloxane (HMDSO), tetramethylcyclotetrasiloxane (TMCTS), tetramethyldisiloxane (TMDS), tetramethyl orthosilicate (TMOS), dimethyldimethoxysilane (DM-DMOS), octamethylcyclotetrasiloxane (OMCTS), bis(triethoxysilyl)methane, TMOCTS. In various embodiments, the reactant comprises one or more of NH₃ and Ar, He and H₂, Ar and N₂, or any other suitable reactants for deposition of silicon films. The substrate temperature during step 106 can be between about 50° C. and about 300° C. or between about 65° C. and about 90° C. In various embodiments, a pressure in the reaction chamber during the deposition step 106 can be controlled to between about 7 Torr and about 12 Torr or between about 9 Torr and about 11 Torr.

Method 100 can further comprise treating the top surface of the deposited material to form a treated deposited material (e.g., a treated deposited material 210) (step 108). The step 108 may be referred to as a treatment step or a cure step. In various embodiments, the treatment step 108 comprises providing a cure gas and vacuum ultraviolet radiation within the reaction chamber to treat the top surface of the deposited material. The cure gas and the vacuum ultraviolet radiation can be introduced at the same time to the reaction chamber to treat the deposited material. In various embodiments, the cure gas is the same as the treatment gas. In various embodiments, a temperature of the reaction chamber during the treatment step 108 is between about 50° C. and about 450° C. or between about 65° C. and about 110° C. In various embodiments, the cure gas used during step 108 can comprise one or more of O₂, NH₃, Ar, N₂, He, H₂ and N₂H₂. In various embodiments, a pressure in the reaction chamber during the treatment step 108 is controlled to between about 7 Torr and about 12 Torr or between about 9 Torr and about 11 Torr. In various embodiments, steps 106 and 108 of method 100 can repeated until a desired composition of the deposited material remains formed on the substrate. The cure gas and the vacuum ultraviolet radiation can be introduced at the same time to the reaction chamber to treat the top surface of the deposited material. The vacuum ultraviolet radiation may comprise electromagnetic radiation with a wavelength of about 200 nm to about 500 nm, or at least 150 nm to 200 nm. In various embodiments, the vacuum ultraviolet radiation can be replaced with a wide range ultraviolet radiation. In various embodiments, a power to form the vacuum ultraviolet radiation is between 100 mW/cm² and 200 mW/cm² or between 125 mW/cm² and about 150 mW/cm².

In various embodiments, the method 100 can be done without a treatment step 104, but still utilize a treatment step 108 after the deposition step 106, to treat the deposited material. In various embodiments, the method 100 can be done without a treatment step 108, but still utilize a treatment step 104 before the deposition step 106, to treat the substrate. In various embodiments, the step 106 can be done in a first reaction chamber, and the steps 102, 104 and 108 can be done in a second reaction chamber of a reactor system. In various embodiments, steps 104, 106, and 108 are each done in a different reaction chamber of a reactor system, wherein a substrate handling robot can move the substrate from reaction chamber to reaction chamber.

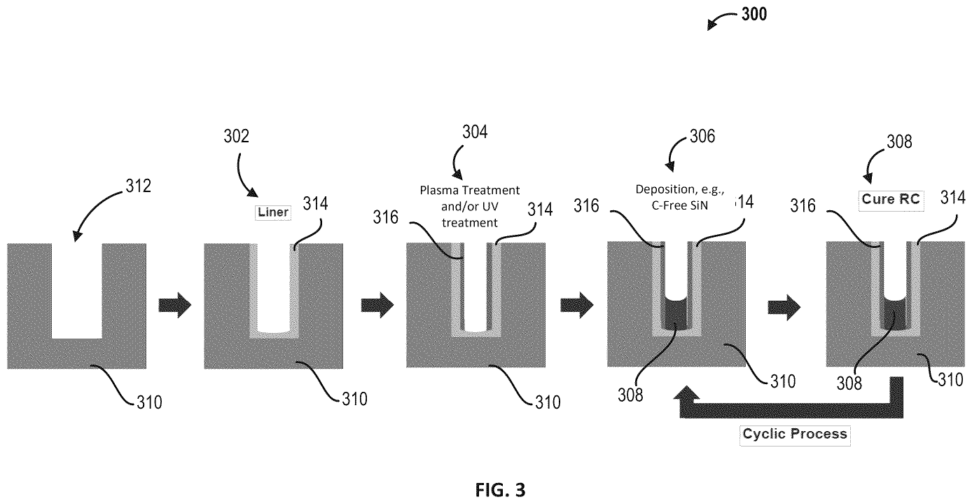

FIG. 3 illustrates steps of a method 300 to form a deposited material on a substrate in accordance with additional examples of the disclosure. Method 300 includes providing, a substrate (e.g., a substrate 310), in a reaction chamber. In various embodiments, the substrate comprises a plurality of gaps (e.g., a gap 312). In various embodiments, the plurality of gaps have an aspect ratio≥17, and a critical dimension≤20 nm or ≤30 nm.

In various embodiments, the method 300 comprises depositing a liner within the plurality of gaps (e.g., a line 314) using one or more precursors (step 302). In various embodiments, the liner is deposited using a plasma-enhanced chemical vapor deposition (PEALD) process. In various embodiments, the liner comprises silicon nitride and/or silicon nitride, and in some cases the liner is silicon nitride or silicon oxide. During step 302, the substrate is heated to a temperature of between 20° C. and 600° C. or between 50° C. and 450° C.

In various embodiments, the precursors and/or reactants used during step 302 can comprise one or more of Si, N, C, O, and H, in any combination. Exemplary liner reactants include an oxygen reactant, which may comprise at least one of molecular oxygen (O₂), carbon dioxide (CO₂), or nitrous oxide (N₂O), and in some a noble reactant comprising at least one of argon, nitrogen, or helium. Exemplary liner precursors may comprise an alkylsilane, such as, for example, dimethylsilane, trimethylsilane, tetramethylsilane, diethylsilane, triethylsilane, tetraethylsilane, t-butylsilane (and derivates thereof), or a silicon precursor comprising two silicon atoms, such as hexamethyldisilane, for example. In some embodiments, the silicon precursor may comprise an arylsilane, such as, for example, phenylsilane, diphenylsilane, triphenylsilane, tetraphenylsilane, dibenzylsilane, tribenzylsilane, or tetrabenzylsilane. In some embodiments, the silicon precursor may comprise an aralkylsilane, such as, for example, trimethyl-(3-methylphenyl)silane, or dimethyl(4-methylphenyl)silane. In some embodiments of the disclosure, the silicon precursor may further comprise at least one of a nitrogen component or an oxygen component. For example, the silicon precursor may comprise at least one of an alkylalkoxysilane or an alkylaminosilane. In some embodiments, the silicon precursor may comprise an alkylalkoxysilane, such as, for example, methyltrimethoxysilane, ethoxy(trimethyl)silane, diethyl-methyl-ethoxysilane, ethyl(dimethyl)-ethoxysilane, tert-butyl-triethoxysilane, or butyl(trimethoxy)silane. In some embodiments, the silicon precursors may comprise an alkylaminosilane, such as, tris(dimethylamino)ethylsilane, for example.

In various embodiments, the method 300 comprises treating a surface of the liner to form a treated surface (e.g., a treated surface 316) (step 304). In various embodiments, treating the surface of the liner can be done by exposing the top surface to a treatment gas. In various embodiments, the treatment gas is exposed to UV radiation, for example vacuum ultraviolet radiation, and in some cases a plasma is formed using the treatment gas. During step 304, the substrate is heated to a temperature of between 20° C. and 600° C. or between 50° C. and 450° C. In various embodiments, the treatment gas used during step 304 can comprise He, O₂, N₂O, CO₂, Ar, N₂, NH₃, H₂, and/or mixture of thereof. In various embodiments, a pressure in the reaction chamber during the treatment step 304 can be controlled to a pressure of, for example, to between about 0.1 Torr and about 30 Torr or between about 0.1 Torr and about 10 Torr.

As discussed, flowability can depend on substrate surface conditions, e.g., surface energy, wettability, temperature or the like. Tuning these parameters can be used to obtain void free material within the gaps. The step 304 of treating the surface of the liner can be used to modify the flowability of any flowable material deposited on the substrate and in the plurality of gaps. Step 304 can improve the wettability of the flowable material and gap fill performance.

Method 300 includes depositing flowable material in the plurality of gaps by providing a precursor and a reactant (step 306). In various embodiments, the flowable material forms deposited material (e.g., deposited material 318). The deposited material has a top surface of the deposited material. In various embodiments, the deposited material is a carbon-free silicon nitride.

In various embodiments, the precursor comprises one or more of silicon, nitrogen, oxygen and hydrogen. For example, the precursor can be represented by the formula Si_{X}N_{Y}C_{Z}O_{A}H_{N}, where X ranges from 1 to 6 Y ranges from 0 to 6, Z ranges from 0 to 20, A ranges from 0 to 10, and N ranges from 0 to 10. By way of examples, the precursor can be or include alkoxy, silanes, siloxanes, silazanes, and amines, such as hexamethyldisilazane, N,N,N′,N′-tetrasilyl-silanediamine, methyltrimethoxysilane, hexamethoxydisiloxane, or any other precursors described herein. In some embodiments, the flowable material comprises a polysilazane. In some embodiments, the precursor comprises a polysilazane oligomer. The polysilazane oligomer may be branched or linear. Suitably, the polysilazane oligomer comprises a plurality of oligomeric species, i.e., the gap filling fluid may comprise various different oligomers, both branched and linear. In some embodiments, a polysilazane oligomer comprises a plurality of different macromolecules that may have a varying morphology.

The flowable material formed herein may comprise hydrogen. In some embodiments, the flowable material that is formed herein comprise from at least 3% to at most 30% H, or from at least 5% to at most 20% H, or from at least 10% to at most 15% H, wherein all percentages are given in atomic percent. Hence, when, for example, a flowable material is referred to as SiN, the breath of the term “SiN” is intended to encompass SiN:H, i.e., SiN comprising hydrogen, e.g., up to 30 atomic percent hydrogen.

In some embodiments, the precursor does not contain any carbon, halogens, or chalcogens. In some embodiments, the precursor does not contain any carbon or chalcogens. In some embodiments, the precursor does not contain any carbon. In some embodiments, the precursor does not contain any chalcogens. For example, in some embodiments, the precursor does not contain any carbon, chlorine, or oxygen. In various embodiments, the precursor does not contain any atoms other than silicon, nitrogen, and hydrogen. In other words, in some embodiments, the precursor essentially consists of silicon, nitrogen, and hydrogen.

In various embodiments, the reactant comprises one or more of NH₃ and Ar, He and H₂, Ar and N₂, or any other suitable reactants for deposition of silicon films. The substrate temperature during step 306 can be between about 20° C. and about 200° C. or between about 50° C. and about 150° C. In various embodiments, a pressure in the reaction chamber during the deposition step 306 can be controlled to between about 4 Torr and about 100 Torr or between about 7 Torr and about 20 Torr.

Method 300 can further comprise treating the top surface of the deposited material to form a treated deposited material (e.g., a treated deposited material 320) (step 308). The step 308 may be referred to as a treatment step or a cure step, and in some embodiments is the same as step 108. Alternatively, step 308 can be a plasma cure. The plasma cure can comprise post-treating the deposited material with an inert gas plasma to increase the density of the deposited material. The post-deposition treatment using a plasma may be carried out by an in-situ plasma treatment method that generates a plasma on the deposited material while supplying an inert gas, for example, argon (Ar) gas and/or helium (He) gas. To further promote densification of the film through an ion bombardment effect, it may be more effective to use at least some argon gas which has a greater atomic mass.

During step 308, the temperature of the substrate inside the reaction chamber may be maintained at a temperature of about 0° C. to about 150° C., for example, about 50° C. to about 150° C. To create a plasma atmosphere inside the reaction chamber, RF power, for example, an RF power in a range of greater than 0 W to about 1,500 W, about 100 W to about 1,000 W, particularly, about 500 W to about 900 W, may be applied. The RF frequency used here may be a frequency of about 10 MHz to about 60 MHz, preferably, about 20 MHz to about 30 MHz. The pressure inside the reaction chamber may be maintained within a range of about 1.0 Torr to about 9.0 Torr, particularly, about 2.0 Torr to about 5.0 Torr. To create a plasma atmosphere in the reaction chamber, exemplary embodiments may utilize an in-situ plasma treatment that generates an inert gas plasma proximate the substrate by applying RF power directly to the reaction chamber while supplying the inert gas to the reaction chamber.

In various embodiments, the steps of methods 100 and 300 can be combined such that a plasma pretreatment (e.g., step 304) is done before depositing flowable material and then curing the deposited material with a vacuum ultraviolet cure (e.g., step 108). Further, in various embodiments, a vacuum ultraviolet pretreatment (e.g., step 104) is done before depositing flowable material and then curing the deposited material with a plasma cure (e.g., step 308).

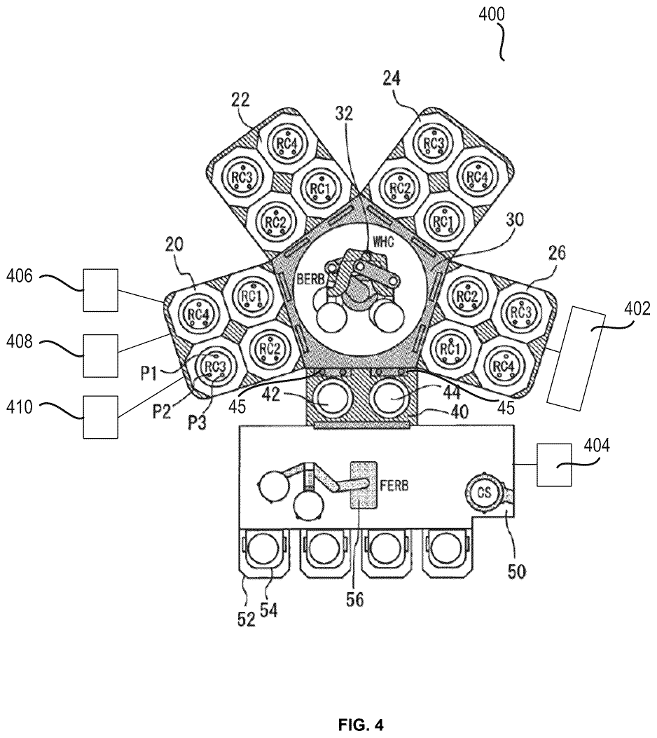

FIG. 4 is a schematic plan view of a reactor system 400 with multiple reaction chambers in accordance with an embodiment of the present invention. Reactor system 400 can be configured to perform various steps (e.g., all steps) of methods 100 and 300 as described above. Reactor system 400 may comprise: (i) two or more (e.g., four) process modules 20, 22, 24, 26, each having four reaction chambers RC1, RC2, RC3, RC4; (ii) a substrate handling chamber 30 including two back end robots 32 (substrate handling robots); and (iii) a load lock chamber 40 for loading or unloading two substrates simultaneously, the load lock chamber 40 being attached to the one additional side of the substrate handling chamber 30, wherein each back end robot 32 is accessible to the load lock chamber 40. Each of the back end robots 32 may have at least two end-effectors accessible to the two reaction chambers of each unit, said substrate handling chamber 30 can have a polygonal shape having four sides corresponding to and being attached to the four process modules 20, 22, 24, 26, respectively, and one additional side for a load lock chamber 40. The interior of each process modules 20, 22, 24, 26 and the interior of the load lock chamber 40 may be isolated from the interior of the substrate handling chamber 30 by at least one gate valve 45. In various embodiments, at least one of the reaction chambers RC1-RC4 in at least one of the process modules 20-26, comprises a vacuum ultraviolet radiation source 402 configured to treat a substrate with vacuum ultraviolet radiation. In various embodiments, at least one of the reaction chambers RC1-RC4 in at least one of the process modules 20-26, are in communication with a reactant source 406, a precursor source 408, and a treatment gas source 410 configured to deposit a flowable material on the substrate. In various embodiments, the reactant source 406 comprises a reactant such as a reactant described above. In various embodiments, the precursor source 408 comprises a precursor as described above. In various embodiments, the treatment gas source 410 comprises one or more of treatment gases as described above.

In some embodiments, a controller 404 may store software programmed to execute sequences of substrate transfer, for example. In various embodiments, the controller 404 is configured to control the reactor system 400 to operate a method described herein. The controller 404 may also: check the status of each process chamber; position substrates in each process chamber using sensing systems; control the reactant source 406, the precursor source 408, the treatment gas source 410, and the vacuum ultraviolet radiation source 402; control an electric box for each module; control a front end robot 56 in an equipment front end module based on a distribution status of substrates stored in FOUP 52 and the load lock chamber 40; control the back end robots 32; and control the control gate valves 45 and other valves.

A skilled artisan may appreciate that the apparatus may include one or more controller(s) programmed or otherwise configured to cause the treatment and deposition processes described elsewhere herein to be conducted. The controller(s) may communicate with the various power sources, vacuum ultraviolet sources, heating systems, pumps, robotics, gas flow controllers, or valves, as will be appreciated by the skilled artisan.

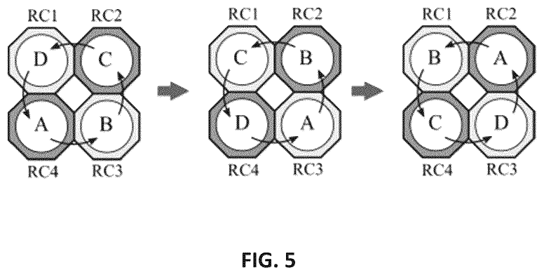

FIG. 5 illustrates exemplary configurations of RC1, RC2, RC3, RC4 of a process module (e.g., process module 20) of reactor system 400. In various embodiments, a substrate may enter the chamber at RC1, at which the substrate may undergo a treatment process (such as the treatment described in step 104), which may include thermal annealing, vacuum ultraviolet, or both. In some embodiments, after undergoing the treatment process, the substrate may be transferred to RC4. Alternatively, the substrate may be transferred to RC2. In either case, the substrate may then undergo a first flowable deposition (such as the deposition described in step 106). After the first treatment process, the substrate may be transferred to RC3, where it may undergo a second treatment process (such as the treatment described in step 108) that may be similar to or the same as the first treatment process. After undergoing the second treatment process, the substrate may be transferred to RC2 if it was previously transferred to RC4 or may be transferred to RC4 if it was previously transferred to RC2. In either case, the substrate may then undergo a second flowable deposition process that is similar to or the same as the first flowable deposition process, if desired.

The cycle may be repeated to achieve desired film quality and thickness. Furthermore, the substrate may enter the chamber at any one of RC1, RC2, RC3, or RC4 and cycle through the stations in any direction. Generally, however, the deposition-treatment cycle will begin with at least one treatment process, followed by at least one flowable deposition process, and then followed by at least one second treatment process. The at least one flowable deposition process may be performed simultaneously on different substrates and/or performed sequentially on a single substrate.

In the illustrated embodiment of FIG. 5, deposition stations and treatment stations of the same type are positioned diagonally. In some embodiments, this configuration may improve efficiency of the method or reactor system. In some embodiments, two or more pairs of reactions chambers perform the same process on two or more substrates in parallel.

The above cyclic concept can also be applied to different numbers of reaction chambers. In some embodiments, a multi-process chamber module as described herein can comprise multiple stations, half of which may be used for flowable deposition and the other half of which may be used for treatment processes. In some embodiments, a multi-process chamber module comprises at least 2 stations, for example at least 2, 3, 4, 5, 6, 7, 8, 9, 10, 11, 12, 13, 14, 15, 16, 17, 18, 19, 20, 30, 40, 50, 100, 150, 200, 250, 300, 400, or 500 stations, including ranges between any two of the listed values. However, the number of stations is not necessarily limited.

In some embodiments, all stations may be equipped with vacuum ultraviolet sources, or half of the stations may be equipped with vacuum ultraviolet sources, or any other number of stations may be equipped with vacuum ultraviolet radiation sources.

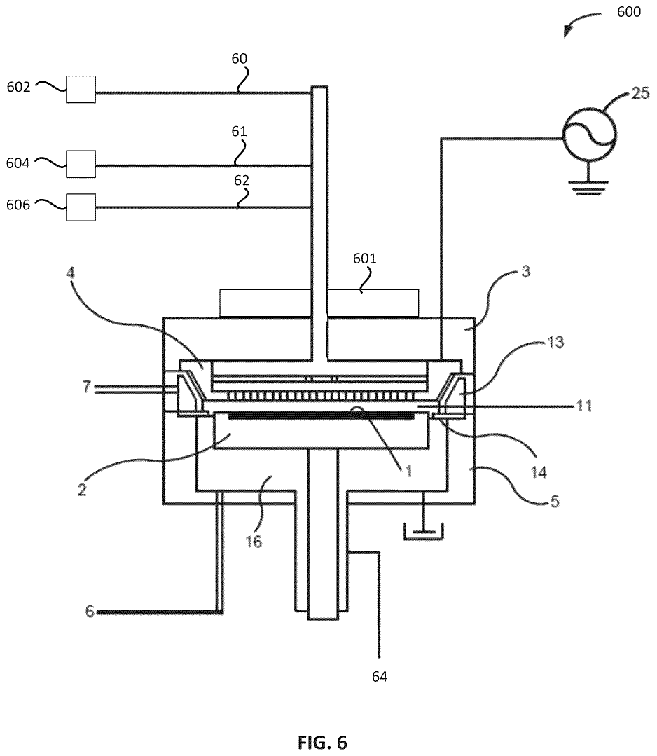

FIG. 6 illustrates a reactor 600 (e.g., RC1) in accordance with exemplary embodiments of the disclosure. The reactor 600 can be used to perform one or more steps or sub steps as described herein and/or to form one or more structures or portions thereof as described herein. Reactor 600 can be used for one or more of RC1-RC4 as described above.

The reactor 600 may include a pair of electrically conductive flat-plate electrodes 4, 2 in parallel and facing each other in an interior 11 (reaction zone) of a reaction chamber 3. A plasma can be excited within the reaction chamber 3 by applying HF power (e.g., 13.56 MHz or 27 MHz) and/or LF power (e.g., 450 k Hz) from a power source 25 to one electrode (e.g., electrode 4) and electrically grounding the other electrode (e.g., electrode 2). A temperature regulator may be provided in a lower stage 2 (the lower electrode), and a temperature of a substrate 1 placed thereon may be kept at a desired temperature. The electrode 4 may serve as a gas distribution device, such as a shower plate. Precursor gas stored in a precursor gas source 602, reactant gas stored in a reactant gas source 604, treatment gas and/or cure gas stored in a treatment gas source, may be introduced into reaction chamber 3 using one or more of a precursor gas line 60, a reactant gas line 61, and a treatment gas line 62 respectively, and through the shower plate 4. Although illustrated with three gas lines, the reactor 600 may include any suitable number of gas lines.

In the reaction chamber 3, a circular duct 13 with an exhaust line 7 may be provided, through which gas in the interior 11 of the reaction chamber 3 may be exhausted. Additionally, a transfer chamber 5, disposed below the reaction chamber 3, may be provided with a seal gas line 64 to introduce seal gas into the interior 11 of the reaction chamber 3 via the interior 16 (transfer zone) of the transfer chamber 5. A separation plate 14 for separating the reaction zone and the transfer zone may be provided. The transfer chamber may be also provided with an exhaust line 6. In some embodiments, the deposition and treatment steps may be performed in the same reaction space, so that two or more (e.g., all) of the steps can continuously be conducted without exposing the substrate to air or other oxygen-containing atmosphere. In various embodiments, the reactor 600 can include a vacuum ultraviolet radiation source 601, which can be the same or similar to vacuum ultraviolet radiation source 402.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A method of forming a structure, the method comprising the steps of:
providing a substrate comprising a plurality of gaps within a reaction chamber;
treating a top surface of the substrate to form a treated surface, the step of treating the top surface comprising exposing the top surface to a treatment gas and ultraviolet radiation; and
depositing flowable material in the plurality of gaps by providing a precursor and a reactant, wherein the flowable material becomes deposited material, and
wherein the step of treating a top surface modifies a flowability of the flowable material.

2. The method of claim 1, wherein the precursor comprises one or more of: silicon, nitrogen, carbon, oxygen and hydrogen.

3. The method of claim 2, wherein the treatment gas comprises one or more of: O₂, NH₃, Ar, N₂, He, H₂ and N₂H₂.

4. The method of claim 3, wherein the reactant comprises one or more of: NH₃—Ar, He—H₂, Ar—N2.

5. The method of claim 2, wherein the flowable material comprises silicon nitride.

6. The method of claim 1, wherein a temperature of the substrate during the depositing the flowable material step is between 50° C. and 300° C. or between 65° C. and 90° C.

7. The method of claim 6, wherein the temperature of the substrate during the treating the top surface step is between 50° C. and 550° C. or between 65° C. and 110° C.

8. The method of claim 7, wherein the ultraviolet radiation comprises a vacuum ultraviolet radiation comprising an electromagnetic radiation with a wavelength between about 120 nm and about 240 nm.

9. The method of claim 1, further comprising treating a top surface of the deposited material to form treated deposited material.

10. The method of claim 9, wherein the depositing the flowable material step and the treating the top surface of the deposited material steps are repeated.

11. The method of claim 10, wherein the step of treating the top surface of the deposited material comprises providing a cure gas and ultraviolet radiation.

12. The method of claim 11, wherein the cure gas is the same as the treatment gas.

13. The method of claim 10, wherein the precursor is intermittently provided in the form of pulses.

14. The method of claim 13, wherein a temperature of the reaction chamber during the treating the top surface of the deposited material step is between 50° C. and 450° C. or between 65° C. and 110° C.

15. The method of claim 14, wherein the depositing the flowable material step is carried out in the reaction chamber, and wherein treating the top surface of the deposited material step is carried out in a second reaction chamber.

16. A reactor system, comprising:
a first reaction chamber configured to deposit a flowable material on a substrate, wherein the substrate comprises a plurality of gaps;
a reactant source comprising a reactant;
a precursor source comprising a silicon precursor;
a treatment gas source, wherein the treatment gas source comprises a treatment gas comprising one or more of O₂, NH₃, Ar, N₂, He, H₂ and N₂H₂;
a vacuum ultraviolet radiation source, wherein the vacuum ultraviolet radiation source is configured to generate a vacuum ultraviolet radiation;
a controller, the controller configured to cause the reactor system to:
perform the method of claim 1.

17. The reactor system of claim 16, wherein the reactor system further comprises a cure gas source comprising a cure gas,
wherein the controller is further configured to cause the reactor system to treat a top surface of the deposited material to form treated deposited material, the step of treating the top surface of the deposited material comprising providing the cure gas and the vacuum ultraviolet radiation.

18. The reactor system of claim 16, further comprising:
a second reaction chamber; and
a wafer handling system,
wherein the vacuum ultraviolet radiation source is configured and arranged for providing the vacuum ultraviolet radiation to the second reaction chamber, the wafer handling system being arranged for transporting one or more wafers between the first reaction chamber and the second reaction chamber.

19. A method of forming a structure, the method comprising the steps of:
providing a substrate comprising a plurality of gaps within a reaction chamber;
depositing a liner within the plurality of gaps;
treating a top surface of the liner to form a treated surface, the step of treating the top surface comprising exposing the top surface to a plasma treatment gas; and
depositing flowable material in the plurality of gaps by providing a precursor and a reactant, wherein the flowable material becomes deposited material, and
wherein the step of treating a top surface modifies a flowability of the flowable material.

20. The method of claim 19, wherein the liner comprises at least one of silicon nitride or silicon oxide.
